(19) United States
(12) Patent Application Publication
(10) Pub. No.: US 2005/0088247 A1
(43) Pub. Date: Apr. 28, 2005

(54) Voltage-controlled oscillator

(75) Inventor: Shoji Yasui, Hamamatsu-shi (JP)

Correspondence Address: PILLSBURY WINTHROP LLP, 725 S. FIGUEROA STREET, SUITE 2800, LOS ANGELES, CA, 90017, US

(73) Assignee: Yamaha Corporation, Hamamatsu-shi (JP)

(21) Appl. No.: 10/970,217

(22) Filed: Oct. 21, 2004

(30) Foreign Application Priority Data
Oct. 22, 2003 (JP) 2003-361815

(51) Int. Cl. H03B 1/00

(52) U.S. Cl. 331/57

(57) ABSTRACT

While an oscillation function is given to a ring oscillator (102) by series-connecting the odd number of logic inverting circuits (INV1 to INV5) to each other and by feeding back an output of the logic inverting circuit provided at a final stage to an input of the logic inverting circuit provided at a first stage, sources of source follower FETs (P21 to P25) for constituting the ring oscillator, which correspond to the logic inverting circuits and whose drains are grounded are connected to nodes of the respective logic inverting circuits on the power supply sides thereof, and a stabilized bias voltage is applied to the respective gates of the source follower FETs.

### BACKGROUND OF THE INVENTION

The present invention relates to a voltage-controlled oscillator. More specifically, the present invention is directed to a ring oscillator.

FIG. 4 indicates a circuit arrangement of a related voltage-controlled oscillator. In this drawing, a voltage-controlled oscillator 1′ contains a voltage-to-current converting circuit 100, a current bias circuit 101, and a ring oscillator 102′. The voltage-to-current converting circuit 100 is constructed of an operational amplifier OP1, a PMOS transistor P0, and a resistor R0. The current bias circuit 101 is constituted by a PMOS transistor P10 and an NMOS transistor N10. A source of the PMOS transistor P10 is connected to a power supply line to which a power supply voltage VDD is applied, and a drain of this PMOS transistor P10 is connected to a drain of the NMOS transistor N10. The drain of the NMOS transistor N10 is short-circuited to a gate thereof, and a source thereof is grounded.

In the voltage-to-current converting circuit 100, the power supply line to which the power supply voltage VDD is applied is connected to the source of the PMOS transistor P0, and the drain thereof is connected via the resistor RO to the ground. A non-inverting input terminal of the operational amplifier OP1 is connected to an input terminal 110, an inverting input terminal of this operational amplifier OP1 is connected to the drain of the PMOS transistor P0, and an output terminal is connected to the drain of the PMOS transistor P0.

In the ring oscillator 102′, “N” stages of inverters “INV1” to “INV5” are connected via a buffer “buf” to each other in a ring shape, where symbol “N” implies an odd number, and is equal to “5” in the example shown in this drawing. This ring oscillator 102′ is arranged in such a manner that one power supply voltage “VDD” is applied via PMOS transistors “P11” to “P15” to the respective inverters INV1 to INV5, whereas the other power supply potential (namely, ground potential) is applied via NMOS transistors “N11” to “N15” to the respective inverters INV1 to INV5.

The gate of the PMOS transistor P10 which constitutes the current bias circuit 101 and gates of the PMOS transistors P11 to P15 are commonly connected to each other, and further, the gate of the NMOS transistor N10 which constitutes the current bias circuit 101 and the gates of the NMOS transistors N11 to N15 are commonly connected to each other, which constitute a current mirror circuit.

In the circuit arrangement, when an input voltage “Vin” is inputted from the input terminal 110 into the non-inverting input of the operational amplifier OP1, assuming now that a resistance value of the resistor R0 is equal to “R”, a current defined by Vin/R flows through this resistor RO via the PMOS transistor P0. At this time, since both the gate of the PMOS transistor P0 of the voltage-to-current converting circuit 100 and the gate of the PMOS transistor P10 of the current bias circuit 101 are fixed to the same potential, the current defined by Vin/R flows through the PMOS transistor P10 and the NMOS transistor N10 (it is so assumed that dimensions of PMOS transistors P0 and P10 are equal to each other).

On the other hand, since both the PMOS transistor P10 and the PMOS transistors P11 to P15, and the NMOS transistor N10 and the NMOS transistors N11 to N15 constitute the current mirror, the respective inverters INV1 to INV5 are driven by a current “I” which is directly proportional to the above-described current “Vin/R.” Assuming now that the current flowing through the respective stages is equal to “I”; the power supply voltage is equal to “VDD”; and a gate capacitance (load capacitance) of the inverters INV1 to INV5 is equal to “C”, the oscillating frequency “f” of the voltage-controlled oscillator 3 which has been arranged in the above-described manner may be expressed as follows:
ƒ∝(I/C)·(1/VDD)
It is so assumed that a delay occurred in the buffer “buf” can be neglected in the above-described formula. As apparent from the foregoing description, the oscillating frequency “f” is inversely proportional to the power supply voltage VDD. As a result, when the power supply voltage VDD is varied, the oscillating frequency “f” is also varied. Of course, the output voltage is similarly varied.

As previously explained, in the ring oscillator having the related circuit arrangement, since both the oscillating frequency and the output voltage (oscillated amplitude) of this ring oscillator are adversely influenced by the variation in the power supply voltage, technical ideas capable of improving this technical aspect have been proposed. For instance, in a patent publication 1, a variation contained in amplitudes caused by a change contained in power supply voltages is decreased by an nch load resistor. In a patent publication 2, a resistance of a V/I converting circuit (voltage-to-current converting circuit) which determines an oscillating frequency is changed, so that a current itself is adjusted. In a patent publication 3, since a ring oscillator is oscillated by employing a voltage-controlled delay element, an adverse influence caused by a power supply voltage is reduced.

Patent publication 1:

Japanese Laid-open Patent Application No. 2001-94404

Patent publication 2:

Japanese Laid-open Patent Application No. 2001-24485

Patent publication 3:

Japanese Laid-open Patent Application No. Sho-58-84524

### SUMMARY OF THE INVENTION

The present invention has been made to solve the above-described problem, and therefore, has an object to provide a voltage-controlled oscillator, the oscillating frequency and the oscillated amplitude of which can be hardly and adversely influenced by a variation contained in power supply voltages.

In order to solve the aforesaid object, the invention is characterized by having the following arrangement.
(1) A voltage-controlled oscillator comprising:

an odd number of logic inverting circuits that are series connected to one another, wherein the logic inverting circuit provided at a final stage is fed back to an input of the logic inverting circuit provided at a first stage so as to constitute a ring oscillator; and

source follower FETs that respectively include grounded drains and sources connected to power supply side nodes of the logic inverting circuit, wherein a stabilized bias voltage is applied to the respective gates of the source follower FETs.
(2) The voltage-controlled oscillator according to (1) further comprising FETs that function as current bias circuits and are respectively connected between the logic inverting circuits and a power supply,

wherein the bias voltage causes the FETs to be operated in a saturation region.
(3) The voltage-controlled oscillator according to (1), wherein the stabilized bias voltage is supplied from a constant current source circuit.

In the present invention, since the stabilized bias voltage is applied to the above-explained source follower FETs, the stabilized voltages are applied to the nodes on the power supply sides of the respective logic inverting circuits. As a consequence, in the voltage-controlled oscillator according to the present invention, both the oscillating frequency thereof and the output voltage thereof (oscillated amplitude thereof) can be made stable.

Since the FETs functioning as the current source, which are connected to the respective logic inverting circuits, are eventually operated in the saturation region, the desirable currents can be supplied to the respective logic inverting circuits.

In the voltage-controlled oscillator according to the present invention, the oscillating frequency and the output voltage of this voltage-controlled oscillator can be hardly and adversely influenced by a variation contained in the power supply voltages.

### BRIEF DESCRIPTION OF THE DRAWINGS

FIG. 1 is a circuit diagram for indicating an arrangement of a ring oscillator according to an embodiment of the present invention.

FIG. 2 is a diagram for representing an example of a bias circuit for supplying a bias voltage to the ring oscillator of this embodiment.

FIG. 3 is a diagram for graphically showing a comparison example as to a relationship between power supply voltages and oscillating frequencies of the ring oscillator according to this embodiment and the ring oscillator having the conventional structure.

FIG. 4 is a circuit diagram for indicating the arrangement of the ring oscillator having the conventional structure.

### DETAILED DESCRIPTION OF PREFERRED EMBODIMENTS

Referring now to drawings, embodiments according to the present invention will be described.

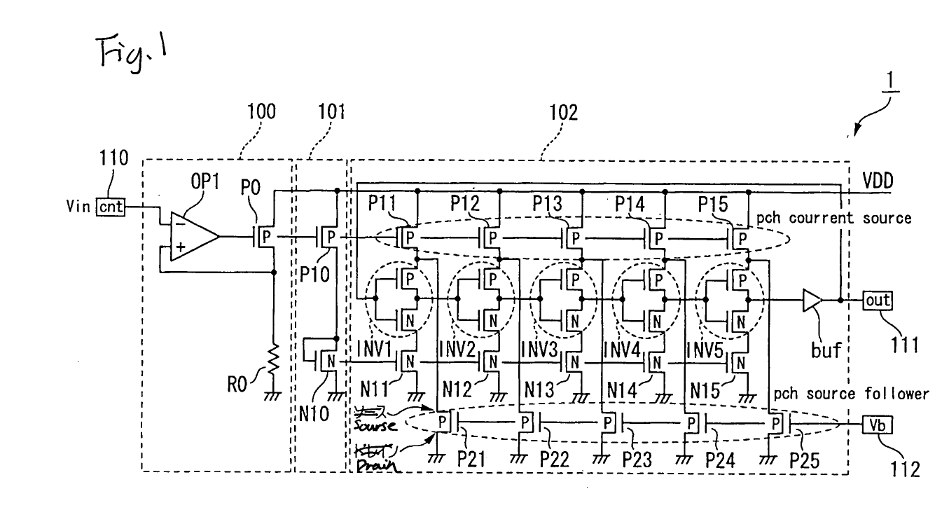

FIG. 1 is a circuit diagram for indicating an arrangement of a voltage-controlled oscillator 1 according to an embodiment of the present invention.

As indicated in this drawing, a ring oscillator 102 which constitutes the voltage-controlled oscillator 1 according to this embodiment includes a different point from the above-described ring oscillator 102′ which constitutes the related voltage-controlled oscillator 1′. That is, this ring oscillator 102 includes such a circuit arrangement that each of sources of source follower FETs (PMOS transistors P21 to P25) whose drains are grounded is connected to each of nodes on the power supply side of each stage of the logic inverting circuits (inverters INV1 to INV5) . Other circuit arrangements of the voltage-controlled oscillator 1 are similar to those of the conventional voltage-controlled oscillator 1′. In the above-described circuit arrangement, a bias voltage “Vb” which has been stabilized and is applied from a bias circuit 2 (will be explained later) is applied to a terminal 112 which is connected to the gates of the respective source follower FETs.

It should be noted that the same reference numerals shown in FIG. 4 will be employed as those for denoting the commonly-used circuit portions in this drawing, and thus, explanations thereof are omitted.

As the above-described bias voltage Vb, such a voltage is employed, while this voltage causes Pch current source FETs (PMOS transistors P11 to P15) shown in this drawing to be operated in saturation regions. For instance, the following voltage is employed as the bias voltage Vb:
Vb=VDD−VDsat−Vb

It should be understood that symbol “VDsat” indicates a saturated drain voltage (pinch-off voltage) of a Pch current source FET shown in this drawing; and symbol “Vt” shows a threshold voltage of a Pch source follower FET (PMOS transistors P21 to P25) shown in this drawing.

As previously explained, assuming now that the gate capacitance of the inventers INV1 to INV5 are equal to “C”, and a current for driving each of the inverters INV1 to INV5 is equal to “I”, and a threshold voltage of a Pch source follower FET is equal to “Vt”, an oscillating frequency “f” of the ring oscillator 102 which is arranged in the above-described manner is expressed as follows:
ƒ∝(I/C)·(1/(Vb+Vt))

In this formula, since the bias voltage “Vb” has been stabilized, the oscillation frequency “f” similarly becomes stable, so that the ring oscillator 102 can be hardly and adversely influenced by the power supply voltage VDD. The output voltage of this ring oscillator 102 becomes stable.

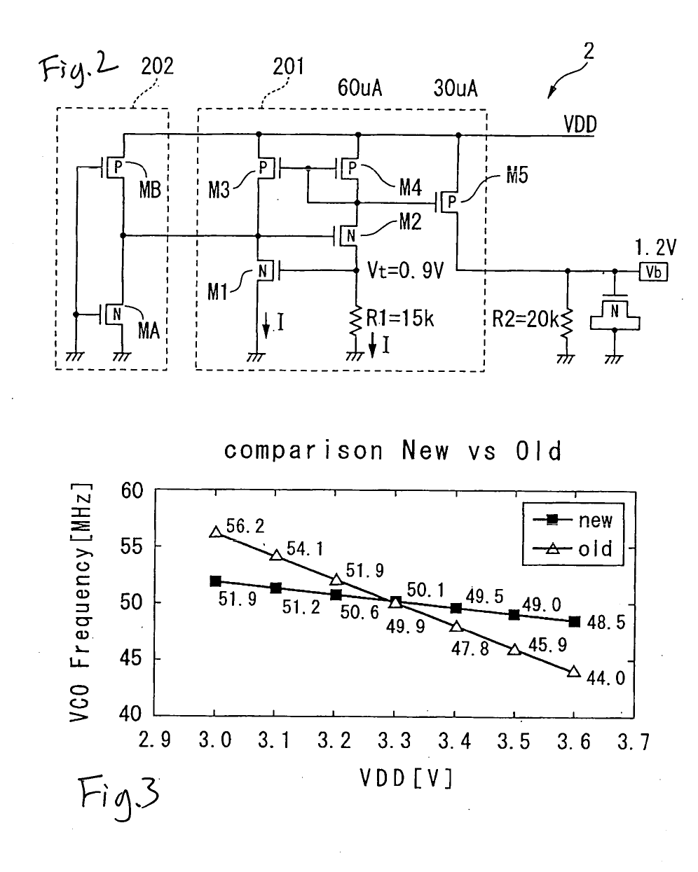

Now, a description is made of an example of the bias circuit which supplies the stabilized bias voltage “Vb” with reference to FIG. 2.

Reference numeral 201 shown in this drawing indicates a self-bias type constant current source circuit. This self-bias type constant current source circuit is known as an effective circuit capable of lowering an adverse influence caused by a variation contained in power voltages. In this bias circuit, since a feedback operation is carried out by an NMOS transistor M2, and PMOS transistors M3 and M4, the same current “I” as that of a resistor R1 may flow through another NMOS transistor M1, and this bias circuit owns an operating point capable of the below-mentioned formula (1). It should be understood that both a channel length modulation effect and a substrate bias effect are neglected (reference publication: P. R. Glay, P. J. Frust, SiH. Lebis, and R. G. Meyer, “Analog Integrated Circuit Design for System LSI, lower volume” published by BAIFUKAN publisher, pages 305 to 306).

$$IR = {V}_{GS1} = {V}_{t1} + \sqrt{\frac{2 I}{μ {nCox ( \frac{W}{L} )}_{1}}} \qquad Formula 1$$

In this formula (1), symbol “I” denotes a current flowing through both the NMOS transistor M1 and the resistor R1; symbol “R” shows a resistance value of the resistor R1; symbol “VGS1” represents a gate-to-source voltage of the NMOS transistor M1; symbol “Vt1” shows a threshold voltage of the NMOS transistor M1; symbol “μn” indicates an electron mobility of the NMOS transistor M1; symbol “Cox” shows a gate oxide film capacitance per unit area of the NMOS transistor M1; and symbol “W” indicates a gate width of the NMOS transistor M1; and symbol “L” denotes a channel length of the NMOS transistor M1.

In the above-described formula (1), in such a case that the second term indicative of a difference (VGS−Vt) is smaller than the first term indicative of the threshold voltage (Vt1), the bias current “I” may be approximated as I=Vt1/R, so that it can be understood that this bias circuit can be hardly influenced by the variation in the power supply voltages. The above-explained difference (VGS−Vt) is obtained by subtracting the gate-to-source voltage VGS of the NMOS transistor M1 by the threshold voltage Vt. Such a case that this difference (VGS−Vt) is smaller than the threshold voltage (Vt1) may be realized by such a manner that, for example, a bias current is selected to be small, and a size ratio defined by channel width W/channel length L is selected to be large. As a result, a constant current may be outputted from the PMOS transistor M5 of this constant current source circuit 1.

Since the output current outputted from the PMOS transistor M5 of the above-described constant current source circuit 1 flows through the resistor R2, the bias circuit shown in FIG. 2 may output the stabilized (constant voltage) bias voltage Vb. It should be noted that a circuit which is indicated by reference numeral 202 and is constituted by an NMOS transistor MA and a PMOS transistor MB corresponds to one example of an initiating circuit provided in order to avoid that a stable balanced condition of the self-bias type constant current source circuit 201 is brought into a not-expected condition. In the constant current source circuit 201 shown in this drawing, a stable point is present under Vt=0, and the initiating circuit 202 pushes up the threshold voltage Vt of the NMOS transistor M1 to a desirable threshold voltage (namely, 0.9 V in this drawing).

As indicated in this drawing, the resistance values of the resistors R1 and R2 are 15 KΩ and 20 KΩ, respectively. If the threshold voltage Vt of the NMOS transistor M1 is equal to 0.9 V and the size ratio of the PMOS transistors M4 and M5 is equal to 2:1, then a current of 60 μA flows through the resistor R1 and another current of 30 μA flows throgh the resistor R2. As a result, 1.2 V is obtained as the bias voltage Vb.

In the above-described example, such a circuit using the self-bias type constant current source circuit has been represented as the bias circuit for supplying the stabilized bias voltage Vb to the Pch source follower FETs (PMOS transistors P21 to P25). Alternatively, if the above-described bias circuit corresponds to a so-called “band gap reference circuit” (which is described in pages 460 to 261 and pages 468 to 469 of “Design of Analog Cmos Integrated Circuit, Application edition, written by Behzad Razavi, translation supervised by Tadahiro Kuroda, published on May 31, 2003, which are expressly incorporated herein by reference in their entireties), and/or another bias circuit which can be hardly and adversely influenced by a variation in power supply voltages, then any of these circuits may be employed.

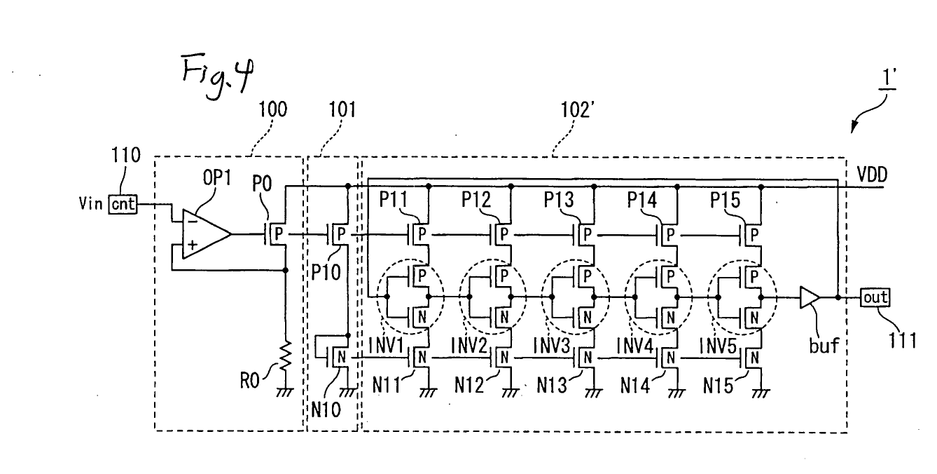

Next, FIG. 3 graphically shows a comparison example as to a relationship between the power supply voltages and the oscillating frequencies of the ring oscillator according to this embodiment and the ring oscillator having the conventional structure.

As represented in this drawing, a gradient of a graph (indicated as “new” in this drawing) between the power supply voltage and the oscillating frequency of the ring oscillator having the structure of this embodiment becomes gentle with respect to a gradient of a graph (denoted as “old” in this drawing) between the power supply voltage and the oscillating frequency of the ring oscillator having the conventional structure. It can be seen that the oscillating frequency of the ring oscillator of this embodiment can be hardly and adversely influenced.

While the embodiment of the present invention has been described in detail with reference to the drawings, the concrete structure thereof is not limited only to this embodiment, but may apparently cover structures defined within the range without departing from the technical spirit of the present invention.

1. A voltage-controlled oscillator comprising:
an odd number of logic inverting circuits that are series connected to one another, wherein the logic inverting circuit provided at a final stage is fed back to an input of the logic inverting circuit provided at a first stage so as to constitute a ring oscillator; and
source follower FETs that respectively include grounded drains and sources connected to power supply side nodes of the logic inverting circuit, wherein a stabilized bias voltage is applied to the respective gates of the source follower FETs.

2. The voltage-controlled oscillator according to claim 1 further comprising FETs that function as current bias circuits and are respectively connected between the logic inverting circuits and a power supply,
wherein the bias voltage causes the FETs to be operated in a saturation region.

3. The voltage-controlled oscillator according to claim 1, wherein the stabilized bias voltage is supplied from a constant current source circuit.
